(19) United States
(12) Patent Application Publication
(10) Pub. No.: US 2015/0004789 A1
(43) Pub. Date: Jan. 1, 2015

(54) SEMICONDUCTOR MANUFACTURING APPARATUS AND METHOD

(71) Applicant: KABUSHIKI KAISHA TOSHIBA, Tokyo (JP)

(72) Inventor: Kenji MATSUZAKI, Yokkaichi-Shi (JP)

(73) Assignee: KABUSHIKI KAISHA TOSHIBA, Tokyo (JP)

(21) Appl. No.: 14/017,513

(22) Filed: Sep. 4, 2013

Related U.S. Application Data
(60) Provisional application No. 61/840,628, filed on Jun. 28, 2013.

(51) Int. Cl. H01L 21/02; H01L 21/3065; H01L 21/027; H01L 21/67

(52) U.S. Cl. CPC H01L 21/02057; H01L 21/67069; H01L 21/3065; H01L 21/027
USPC 438/694; 156/345.28

(57) ABSTRACT

In one embodiment, a semiconductor manufacturing apparatus includes a chamber configured to house a wafer, and a heater stage configured to support and heat the wafer in the chamber. The apparatus further includes a plasma tube connected to the chamber, and in which plasma is generated, and a coil wound around the plasma tube, and in which a current for generating the plasma flows. The apparatus further includes a plasma controller configured to control the current to be flown in the coil to change a generating position of the plasma in an axial direction of the plasma tube.

### CROSS REFERENCE TO RELATED APPLICATION

This application is based upon and claims the benefit of priority from the prior U.S. Provisional Patent Application No. 61/840,628 filed on Jun. 28, 2013, the entire contents of which are incorporated herein by reference.

### FIELD

Embodiments described herein relate to a semiconductor manufacturing apparatus and method.

### BACKGROUND

A resist layer on a wafer is removed by using, for example, an ashing apparatus using plasma. In this process, when a wafer temperature needs to be decreased, a distance between the wafer and a heater stage is increased by elevating lift pins that support the wafer, thereby reducing a thermal influence of the heater stage on the wafer. However, when the wafer is lifted in the ashing apparatus that is generating the plasma, a distance between a generating position of the plasma and the wafer decreases, and therefore the thermal influence of the plasma on the wafer may be increased. For this reason, when the wafer is lifted in order to decrease the wafer temperature, the wafer temperature may be raised to the contrary. Furthermore, when the resist layer used as a mask for impurity implantation is removed, popping of the resist layer may be generated if the wafer temperature is set to a high temperature.

### BRIEF DESCRIPTION OF THE DRAWINGS

FIG. 1 is a schematic diagram showing a structure of a semiconductor manufacturing apparatus of a first embodiment;

FIG. 2 is a schematic diagram showing a structure of a semiconductor manufacturing apparatus of a second embodiment;

FIG. 3 is a schematic diagram showing a structure of a semiconductor manufacturing apparatus of a third embodiment;

FIGS. 4A to 4D are cross-sectional views showing a semiconductor manufacturing method of a fourth embodiment; and

FIGS. 5A to 5D are cross-sectional views showing a semiconductor manufacturing method of a fifth embodiment.

### DETAILED DESCRIPTION

Embodiments will now be explained with reference to the accompanying drawings.

In one embodiment, a semiconductor manufacturing apparatus includes a chamber configured to house a wafer, and a heater stage configured to support and heat the wafer in the chamber. The apparatus further includes a plasma tube connected to the chamber, and in which plasma is generated, and a coil wound around the plasma tube, and in which a current for generating the plasma flows. The apparatus further includes a plasma controller configured to control the current to be flown in the coil to change a generating position of the plasma in an axial direction of the plasma tube.

### First Embodiment

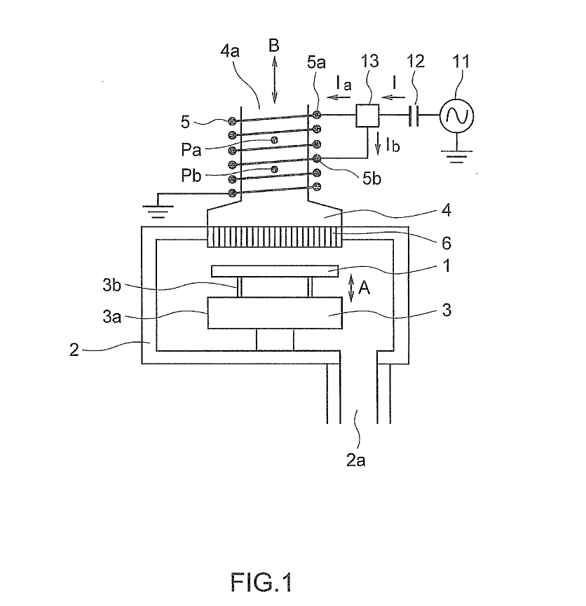

FIG. 1 is a schematic diagram showing a structure of a semiconductor manufacturing apparatus of a first embodiment. The apparatus of FIG. 1 is an ashing apparatus for removing a resist layer on a wafer 1 by ashing with inductive coupling plasma.

The semiconductor manufacturing apparatus of FIG. 1 includes a chamber 2, a heater stage 3, a plasma tube 4, a coil 5, a gas inlet plate 6, a radio frequency (RF) power supply 11, a capacitor 12 and a distributor 13. The RF power supply 11, the capacitor 12 and the distributor 13 of FIG. 1 are an example of a plasma controller.

The chamber 2 houses the wafer 1 to be processed. The chamber 2 of the present embodiment is an ashing chamber for removing the resist layer on the wafer 1 by ashing with the plasma. A reference sign 2a indicates a discharge opening for discharging a gas in the chamber 2.

The heater stage 3 supports and heats the wafer 1 in the chamber 2. The heater stage 3 of the present embodiment includes a heater stage main body 3a that heats the wafer 1, and a plurality of lift pins 3b that support the wafer 1. As shown by an arrow A, the lift pins 3b can change a distance between the wafer 1 and the heater stage main body 3a by lifting and descending the wafer 1. A set temperature of the heater stage main body 3a is, for example, 250° C. to 350° C.

In this specification, a direction from bottom to top of a sheet surface is considered an upward direction, and a direction from the top to the bottom of the sheet surface is considered a downward direction. For example, a positional relationship of the wafer 1 and the heater stage 3 is expressed that the wafer 1 is positioned above the heater stage 3. Furthermore, in this specification, the wafer 1 moving in the upward direction of the sheet surface is expressed as lifting of the wafer 1, and the wafer 1 moving in the downward direction of the sheet surface is expressed as descending of the wafer 1.

The plasma is generated in the plasma tube 4 that is connected to the chamber 2 via the gas inlet plate 6. A reference sign 4a indicates a gas introducing opening for introducing a gas into the plasma tube 4. The plasma tube 4 and the gas inlet plate 6 are arranged above the heater stage 3.

A current for generating the plasma flows in the coil 5 that is wound around the plasma tube 4. When an RF current flows in the coil 5, the gas introduced from the gas introducing opening 4a is formed into plasma, so that inductive coupling plasma is generated in the plasma tube 4. The number of wires forming the coil 5 and the number of turns of the wires can arbitrarily be set.

The RF power supply 11 generates the RF current to be flown in the coil 5. A frequency of the RF current is for example 13.56 MHz. The RF current from the RF power supply 11 is supplied to the distributor 13 via the capacitor 12. A reference sign I indicates the RF current supplied to the distributor 13.

The distributor 13 distributes the current I from the RF power supply 11 into a first current Ia supplied to a first point 5a of the coil 5 and a second current Ib supplied to a second point 5b of the coil 5. The first point 5a and the second point 5b are different points in the coil 5. In the present embodiment, the first point 5a is positioned at an upper end of the coil 5, and the second point 5b is positioned at a center portion between the upper end and a lower end of the coil 5. The first current Ia flows from the upper end to the lower end of the coil 5, and the second current Ib flows from the center portion to the lower end of the coil 5.

The distributor 13 can change a generating position of the plasma in the plasma tube 4 in an axial direction of the plasma tube 4 by changing a current ratio of the first and second currents Ia and Ib. Specifically, the distributor 13 can change a peak position of a density distribution of the plasma in the axial direction by changing the current ratio.

A reference sign B indicates the axial direction of the plasma tube 4. The axial direction B of the plasma tube 4 in the present embodiment is set parallel to an elevating and descending direction A of the lift pins 3b.

Reference signs Pa and Pb respectively indicate peak positions of the density distribution of the plasma when the current ratio Ia/Ib is Ka and Kb where Ka>Kb. As can be understood from a positional relationship of the peak positions Pa and Pb, the distributor 13 can move the peak position of the density distribution of the plasma upward by increasing the current ratio Ia/Ib, so that a thermal influence of the plasma on the wafer 1 can be reduced.

In this way, the distributor 13 of the present embodiment can change the generating position of the plasma in the axial direction of the plasma tube 4 by controlling the current to be flown in the coil 5. The distributor 13 may be capable of continuously adjusting a value of the current ratio Ia/Ib (for example, being capable of adjusting within a range of Kmin to Kmax), or may be capable of discretely adjusting the value of the current ratio Ia/Ib (for example, being capable of adjusting to one of K1, K2, . . . , and Kn).

### Effects of First Embodiment

Effects of the first embodiment will be described.

When the wafer temperature needs to be decreased, the semiconductor manufacturing apparatus of the present embodiment increases the distance between the wafer 1 and the heater stage main body 3a by elevating the lift pins 3b, thereby reducing a thermal influence of the heater stage 3 on the wafer 1.

In this process, the semiconductor manufacturing apparatus of the present embodiment further reduces a thermal influence of the plasma on the wafer 1 by increasing the current ratio Ia/Ib by the distributor 13 to move the peak position of the density distribution of the plasma upward.

In this way, the semiconductor manufacturing apparatus of the present embodiment can reduce the thermal influences of the heater stage 3 and the plasma on the wafer 1, and can therefore decrease the wafer temperature.

Furthermore, since the semiconductor manufacturing apparatus of the present embodiment can decrease the wafer temperature by elevating the lift pins 3b and operating the distributor 13, the wafer temperature can be decreased without using a cooler. Therefore, according to the present embodiment, cost of installing the cooler in the semiconductor manufacturing apparatus can be cut back.

Moreover, according to the present embodiment, when the resist layer used as a mask for impurity implantation is removed by ashing, an occurrence of popping of the resist layer can be suppressed by maintaining the wafer temperature at a low temperature. This effect of suppressing the popping will be described later in a fifth embodiment.

When the lift pins 3b are elevated by a distance D in order to decrease the wafer temperature, it is preferable to move the peak position of the density distribution of the plasma upward by the distance D. A maximum elevating and descending distance of the lift pins 3b of the present embodiment is, for example, 10 to 30 mm. In this case, it is preferable that the distributor 13 of the present embodiment is configured to be capable of moving the peak position of the density distribution of the plasma by 10 to 30 mm.

As described above, according to the present embodiment, the temperature of the wafer 1 which receives the thermal influences of the heater stage 3 and the plasma can appropriately be controlled by changing the generating position of the plasma in the axial direction of the plasma tube 4.

### Second Embodiment

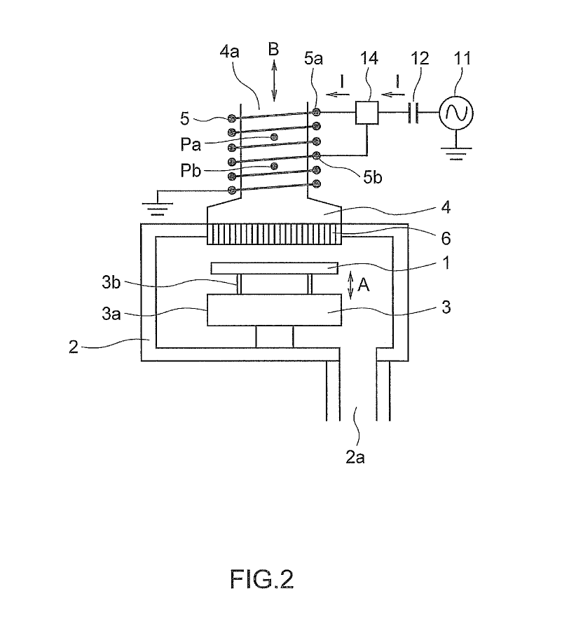

FIG. 2 is a schematic diagram showing a structure of a semiconductor manufacturing apparatus of a second embodiment.

The semiconductor manufacturing apparatus of FIG. 2 includes a switch 14 instead of the distributor 13. The RF power supply 11, the capacitor 12, and the switch 14 of FIG. 2 are an example of the plasma controller.

The switch 14 can change the generating position of the plasma in the plasma tube 4 in the axial direction of the plasma tube 4 by switching a point where the current I from the RF power supply 11 is supplied from one of the first and second points 5a and 5b in the coil 5 to the other of the first and second points 5a and 5b in the coil 5. Specifically, the switch 14 can change the peak position of the density distribution of the plasma in the axial direction by this switching.

Reference signs Pa and Pb respectively indicate the peak positions of the density distribution of the plasma when the current I is supplied to the first and second points 5a and 5b. As can be understood from the positional relationship of the peak positions Pa and Pb, the switch 14 can move the peak position of the density distribution of the plasma upward by switching the point where the current I is supplied from the second point 5b to the first point 5a, so that the thermal influence of the plasma on the wafer 1 can be reduced.

According to the present embodiment, similarly to the first embodiment, the temperature of the wafer 1 which receives the thermal influences of the heater stage 3 and the plasma can appropriately be controlled by changing the generating position of the plasma in the axial direction of the plasma tube 4.

The switch 14 of the second embodiment has an advantage that it can be realized by a simple configuration compared to the distributor 13 of the first embodiment. On the other hand, the distributor 13 of the first embodiment has an advantage that a configuration that enables a fine adjustment of the generating position of the plasma can more easily be realized compared to the switch 14 of the second embodiment.

Although the switch 14 of the second embodiment is configured to be capable of selecting the point where the current I is supplied from two points in the coil 5, it may be configured to be capable of selecting the point where the current I is supplied from three or more points in the coil 5.

### Third Embodiment

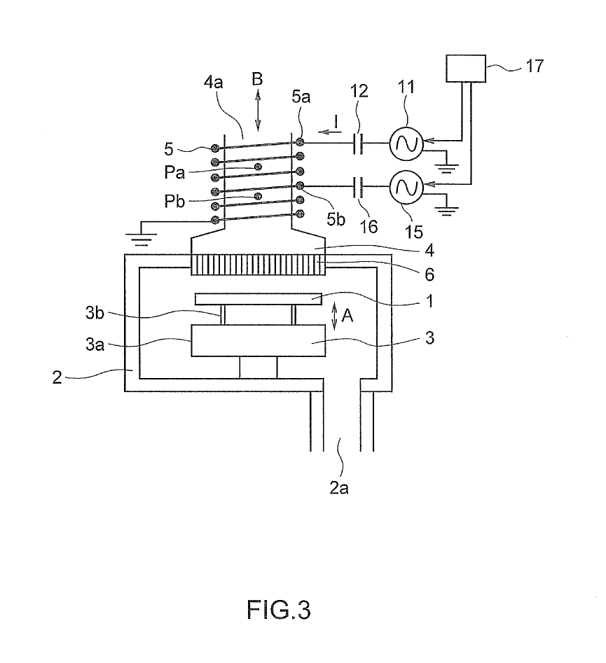

FIG. 3 is a schematic diagram showing a structure of a semiconductor manufacturing apparatus of a third embodiment. In the description of the present embodiment, the RF power supply 11 and the capacitor 12 will respectively expressed as a first RF power supply 11 and a first capacitor 12.

The semiconductor manufacturing apparatus of FIG. 3 includes a second RF power supply 15, a second capacitor 16 and a current controller 17 instead of the distributor 13 and the switch 14. The first RF power supply 11, the first capacitor 12, the second RF power supply 15, the second capacitor 16 and the current controller 17 of FIG. 3 are an example of the plasma controller.

The first and second RF power supplies 11 and 15 respectively generate first and second currents (RF currents) supplied to the first and second points 5a and 5b of the coil 5. Frequencies of the first and second currents may be of the same value, or be of different values. The frequencies of the first and second currents of the present embodiment are both 13.56 MHz. Similarly, amplitudes of the first and second currents may be of the same value, or be of different values. The first and second currents are respectively supplied to the first and second points 5a and 5b via the first and second capacitors 12 and 16.

The current controller 17 can change the generating position of the plasma in the plasma tube 4 in the axial direction of the plasma tube 4 by switching the current supplied to the coil 5 from one of the first and second currents to the other of the first and second currents. Specifically, the current controller 17 can change the peak position of the density distribution of the plasma in the axial direction by this switching. The current controller 17 of the present embodiment can perform this switching by turning on one of the first and second RF power supplies 11 and 15 and turning off the other of the first and second RF power supplies 11 and 15.

Reference signs Pa and Pb respectively indicate the peak positions of the density distribution of the plasma when the first and second currents are supplied to the first and second points 5a and 5b. As can be understood from the positional relationship of the peak positions Pa and Pb, the current controller 17 can move the peak position of the density distribution of the plasma upward by switching the current supplied to the coil 5 from the second current to the first current, so that the thermal influence of the plasma on the wafer 1 can be reduced.

According to the present embodiment, similarly to the first and second embodiments, the temperature of the wafer 1 which receives the thermal influences of the heater stage 3 and the plasma can appropriately be controlled.

Although the current controller 17 of the present embodiment is configured to be capable of selecting the RF power supply that supplies the current to the coil 5 from two RF power supplies, it may be configured to be capable of selecting the RF power supply that supplies the current to the coil 5 from among three or more RF power supplies.

The semiconductor manufacturing apparatus of the present embodiment may be configured to switch the on and off of the first and second RF power supplies 11, 15 by a manual operation of a user.

### Fourth Embodiment

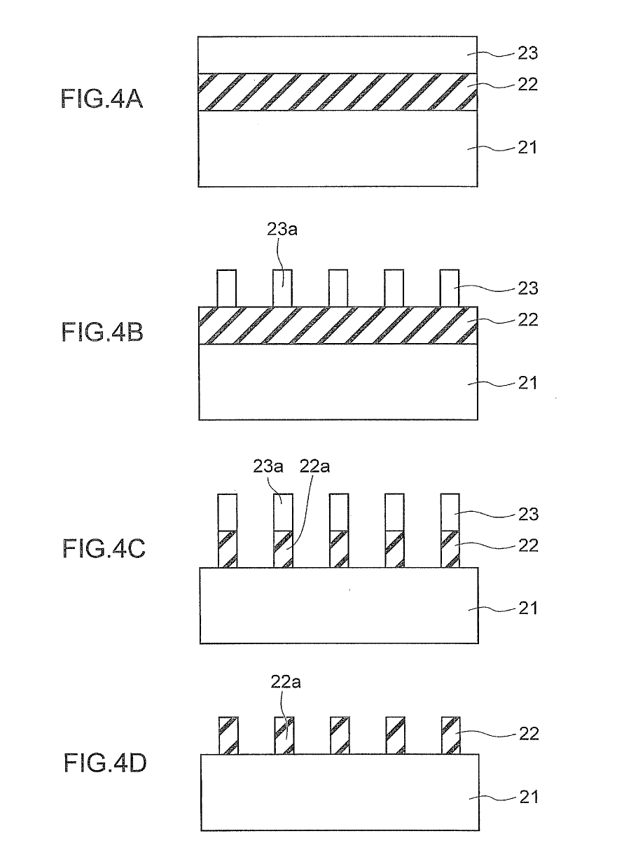

FIGS. 4A to 4D are cross-sectional views showing a semiconductor manufacturing method of a fourth embodiment.

First, as shown in FIG. 4A, a workpiece layer 22 and a resist layer 23 are sequentially formed on a substrate 21. The substrate 21 corresponds to the wafer 1 of FIGS. 1 to 3. Although the workpiece layer 22 in the present embodiment is an insulator, it may be a conductive layer or a semiconductor layer. Furthermore, the workpiece layer 22 may be a stack layer including a plurality of layers.

As shown in FIG. 4B, the resist layer 23 is then patterned by lithography to be processed into a resist mask 23a.

As shown in FIG. 4C, the workpiece layer 22 is then processed into a desired pattern 22a by etching using the resist layer 23 (resist mask 23a).

Thereafter, the substrate 21 (wafer 1) is housed in the chamber 2 of the semiconductor manufacturing apparatus of one of the first to third embodiments, and is mounted on the heater stage 3. The resist layer 23 on the substrate 21 is then removed by ashing with the plasma while the substrate 21 is heated by the heater stage 3 (FIG. 4D).

When the wafer temperature needs to be decreased during this ashing, the semiconductor manufacturing apparatus elevates the lift pins 3b and moves the generating position of the plasma upward. In this way, the semiconductor manufacturing apparatus can reduce the thermal influences of the heater stage 3 and the plasma on the wafer 1, and can therefore decrease the wafer temperature.

As described above, according to the present embodiment, the temperature of the wafer 1 which receives the thermal influences of the heater stage 3 and the plasma can appropriately be controlled when the resist layer 23 on the wafer 1 is removed by the ashing.

### Fifth Embodiment

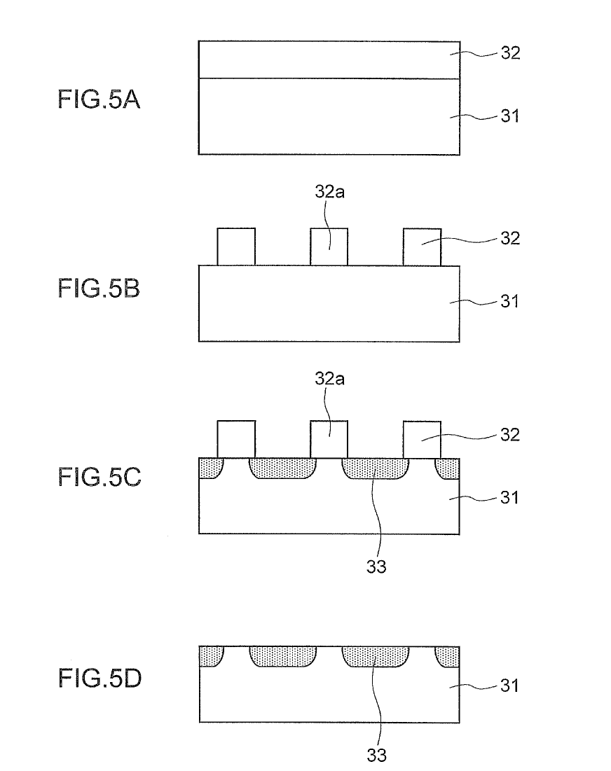

FIGS. 5A to 5D are cross-sectional views showing a semiconductor manufacturing method of a fifth embodiment.

First, as shown in FIG. 5A, a resist layer 32 is formed on a substrate 31. The substrate 31 corresponds to the wafer 1 of FIGS. 1 to 3.

As shown in FIG. 5B, the resist layer 32 is then patterned by lithography to be processed into a resist mask 32a.

As shown in FIG. 5C, impurities are then implanted in predetermined regions of the substrate 31 by using the resist layer 32 (resist mask 32a). As a result, diffusion layers 33 are formed in the substrate 31 by going through a subsequent heating step.

Thereafter, the substrate 31 (wafer 1) is housed in the chamber 2 of the semiconductor manufacturing apparatus of one of the first to third embodiments, and is mounted on the heater stage 3. The resist layer 32 on the substrate 31 is then removed by ashing with the plasma while the substrate 31 is heated by the heater stage 3 (FIG. 5D).

When the wafer temperature needs to be decreased during this ashing, the semiconductor manufacturing apparatus elevates the lift pins 3b and moves the generating position of the plasma upward. In this way, the semiconductor manufacturing apparatus can reduce the thermal influences of the heater stage 3 and the plasma on the wafer 1, and can therefore decrease the wafer temperature.

### Effects of Fifth Embodiment

Effects of the fifth embodiment will be described.

The impurities in the step of FIG. 5C are implanted not only into the substrate 31 but also into the resist layer 32. In this case, if a dose amount of the impurities is large, an altered layer is formed on a surface of the resist layer 32. Since the altered layer is a dense layer, volatile components in the resist layer 32 cannot pass through the altered layer. In this case, if the temperature of the substrate 31 during the ashing is set to a high temperature in order to remove the altered layer, the volatile components in the resist layer 32 expand, so that the popping is generated in which the altered layer explodes before the altered layer is removed. If the popping is generated, a failure of the semiconductor device may occur due to dust caused by the popping, and therefore a normal operation of the semiconductor device may be obstructed.

Accordingly, the semiconductor manufacturing method of the present embodiment performs the ashing while maintaining the wafer temperature at a low temperature for long time. Therefore, according to the present embodiment, the altered layer can be removed while suppressing the popping, so that the resist layer 32 can be removed. Therefore, according to the present embodiment, the generation of the dust caused by the popping can be suppressed, the failure of the semiconductor device can be reduced, and a satisfactory operation of the semiconductor device can be realized.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A semiconductor manufacturing apparatus comprising:
a chamber configured to house a wafer;
a heater stage configured to support and heat the wafer in the chamber;
a plasma tube connected to the chamber, and in which plasma is generated;
a coil wound around the plasma tube, and in which a current for generating the plasma flows; and
a plasma controller configured to control the current to be flown in the coil to change a generating position of the plasma in an axial direction of the plasma tube.

2. The apparatus of claim 1, wherein the plasma controller comprises:
a power supply configured to generate the current to be flown in the coil, and
a distributor configured to distribute the current from the power supply into a first current supplied to a first point in the coil and a second current supplied to a second point in the coil.

3. The apparatus of claim 2, wherein the distributor changes the generating position of the plasma by changing a current ratio of the first and second currents.

4. The apparatus of claim 2, wherein
the first point is positioned on a first end of the coil, and
the second point is positioned between the first end and a second end of the coil.

5. The apparatus of claim 1, wherein the plasma controller comprises:
a power supply configured to generate the current to be flown in the coil, and
a switch configured to change the generating position of the plasma by switching a point where the current from the power supply is supplied from one of first and second points in the coil to the other of the first and second points in the coil.

6. The apparatus of claim 1, wherein the plasma controller comprises:
a first power supply configured to generate a first current supplied to a first point in the coil, and
a second power supply configured to generate a second current supplied to a second point in the coil.

7. The apparatus of claim 6, wherein the plasma controller further comprises a current controller configured to change the generating position of the plasma by switching the current supplied to the coil from one of the first and second currents to the other of the first and second currents.

8. The apparatus of claim 1, wherein the heater stage comprises:
a heater stage main body configured to heat the wafer, and
a lift pin configured to support the wafer, and to change a distance between the wafer and the heater stage main body by lifting and descending the wafer.

9. The apparatus of claim 1, wherein the chamber is an ashing chamber for removing a resist layer on the wafer by using the plasma.

10. The apparatus of claim 1, wherein the plasma controller changes a peak position of a density distribution of the plasma in the axial direction of the plasma tube.

11. A semiconductor manufacturing method comprising:
housing a wafer in a chamber connected to a plasma tube;
supporting and heating the wafer by a heater stage in the chamber;
generating plasma in the plasma tube by a current flowing in a coil wound around the plasma tube; and
changing a generating position of the plasma in an axial direction of the plasma tube by controlling the current to be flown in the coil.

12. The method of claim 11, wherein the generating position of the plasma is changed by changing a current ratio of a first current supplied to a first point in the coil and a second current supplied to a second point in the coil.

13. The method of claim 12, wherein
the first point is positioned on a first end of the coil, and
the second point is positioned between the first end and a second end of the coil.

14. The method of claim 11, wherein the generating position of the plasma is changed by switching a point where the current is supplied in the coil from one of first and second points in the coil to the other of the first and second points in the coil.

15. The method of claim 11, wherein the generating position of the plasma is changed by switching the current supplied to the coil from one of a first current from a first power supply and a second current from a second power supply to the other of the first and second currents.

16. The method of claim 11, wherein the heater stage comprises:
a heater stage main body configured to heat the wafer, and
a lift pin configured to support the wafer, and to change a distance between the wafer and the heater stage main body by lifting and descending the wafer.

17. The method of claim 11, wherein the chamber is an ashing chamber for removing a resist layer on the wafer by using the plasma.

18. The method of claim 11, wherein a peak position of a density distribution of the plasma is changed in the axial direction of the plasma tube by controlling the current to be flown in the coil.

19. The method of claim 11, further comprising:
forming a resist layer on the wafer;
processing the resist layer into a resist mask by lithography;
housing the wafer in the chamber after using the resist layer as the resist mask; and
removing the resist layer by ashing with the plasma.

20. The method of claim 19, wherein the generating position of the plasma is changed in the axial direction of the plasma tube by controlling the current to be flown in the coil during the ashing.
